(19) United States
(12) Patent Application Publication
(10) Pub. No.: US 2026/0230725 A1
(43) Pub. Date: Aug. 6, 2026

(54) PIXEL ARRANGEMENT WITH TWO TRANSFER TRANSISTORS AND METHOD FOR OPERATING THE PIXEL ARRANGEMENT

(71) Applicant: ams Sensors USA Inc., PLANO, TX (US)

(72) Inventor: Denver LLOYD, BOISE, ID (US)

(73) Assignee: ams Sensors USA Inc., PLANO, TX (US)

(21) Appl. No.: 19/149,035

(22) PCT Filed: Jan. 19, 2024
(86) PCT No.: PCT/US2024/012108

§ 371 Date: Jul. 17, 2025

Related U.S. Application Data
(60) Provisional application No. 63/481,027, filed on Jan. 23, 2023.

(51) Int. Cl. H04N 25/59; H04N 25/51; H04N 25/766; H10F 39/00

(52) U.S. Cl. CPC H04N 25/59; H04N 25/766; H10F 39/802; H04N 25/51

(57) ABSTRACT

A pixel arrangement comprises a photodiode, a first and a second circuit node, a first transfer transistor coupled to the photodiode and to the first circuit node, a second transfer transistor coupled to the photodiode and to the second circuit node, an amplifier with an input coupled to the first circuit node, a supply terminal, a first and a second coupling transistor, and a reset transistor. The first coupling transistor, the second coupling transistor and the reset transistor are serially coupled and are arranged between the supply terminal and the first circuit node. The 15 second circuit node is arranged between the second coupling transistor and the reset transistor.

### CROSS-REFERENCE TO RELATED APPLICATIONS

The present application is the national stage entry of International Patent Application No. PCT/US2024/012108, filed on Jan. 19, 2024, and published as WO 2024/158634 A1 on Aug. 2, 2024, which claims the benefit of U.S. Provisional Patent Application No. 63/481,027, filed on Jan. 23, 2023, the disclosures of all of which are incorporated by reference herein in their entireties.

### TECHNICAL FIELD

Various embodiments of the present disclosure relate to a pixel arrangement, an image sensor and a method for operating a pixel arrangement.

### BACKGROUND

An image sensor typically includes an array of pixel arrangements. A high dynamic range for the conversion of electromagnetic radiation into an electrical signal is beneficial. However, a size of a pixel arrangement shall be kept small.

### SUMMARY

In an embodiment of the present disclosure, a pixel arrangement comprises a photodiode, a first and a second circuit node, a first transfer transistor coupled to the photodiode and to the first circuit node, a second transfer transistor coupled to the photodiode and to the second circuit node, an amplifier with an input coupled to the first circuit node, a supply terminal, a first and a second coupling transistor, and a reset transistor. The first coupling transistor, the second coupling transistor and the reset transistor are serially coupled and are arranged between the supply terminal and the first circuit node. The second circuit node is arranged between the second coupling transistor and the reset transistor.

Advantageously, charge can be transferred from the photodiode through several paths. The charge of the photodiode is transferred e.g. via the first transfer transistor to the first circuit node and is available at the input of the amplifier. Charge at the first node is transferred to the supply terminal via the first and the second coupling transistor and the reset transistor. Moreover, charge of the photodiode is transferred e.g. via the second transfer transistor and the reset transistor to the supply terminal. Thus, this charge flows from the photodiode to the supply terminal without contributing to an input voltage at the input of the amplifier. Charge of the photodiode is transferred e.g. via the second transfer transistor and the first and the second coupling transistor to the first circuit node. The different paths can be used parallel or one after the other. Thus, a high variability is achieved which allows to convert low light and also high light received by the photodiode into an accurate output signal of the pixel arrangement.

In an embodiment of the pixel arrangement, a first terminal of the first coupling transistor is coupled or connected to the first circuit node. A second terminal of the first coupling transistor is coupled or connected to a first terminal of the second coupling transistor. A second terminal of the second coupling transistor is coupled or connected to a first terminal of the reset transistor via the second circuit node. A second terminal of the reset transistor is coupled or connected to the supply terminal.

In an embodiment, in an exposure phase the pixel arrangement is configured to set the first transfer transistor and the reset transistor in a conducting state for a first pulse period. Furthermore, in the exposure phase, the pixel arrangement is configured to set the second transfer transistor in a conducting state and in a non-conducting state during the first pulse period of the first transfer transistor.

In an embodiment, in the exposure phase the pixel arrangement is configured to set the first transfer transistor in a conducting state for a second pulse period and in a non-conducting state during an in-between period between the first pulse period and the second pulse period. Furthermore, in the exposure phase, the pixel arrangement is configured to set the reset transistor in a conducting state during the second pulse period and during the in-between period between the first pulse period and the second pulse period. Moreover, in the exposure phase, the pixel arrangement is configured to set the second transfer transistor in a conducting state and in a non-conducting state in the in-between period between the first pulse period and the second pulse period and to set the second transfer transistor in a conducting state and in a non-conducting state during the second pulse period of the first transfer transistor.

In an embodiment, the pixel arrangement is configured to set the first transfer transistor in a conducting state during pulses of a first series of pulses and to set the first transfer transistor in a non-conducting state during in-between periods between pulses of the first series of pulses. Furthermore, in the exposure phase, the pixel arrangement is configured to set the reset transistor in a conducting state during the pulses of the first series of pulses and during the in-between periods between the pulses of the first series of pulses. The number of pulses of the first series of pulses is at least 1 or at least 2 or at least 3.

In an embodiment, in the exposure phase, the pixel arrangement is configured to set the second transfer transistor in a conducting state during pulses of a second series of pulses and in a non-conducting state during in-between periods between the pulses of the second series of pulses. The pixel arrangement is configured to perform the first and the second series of pulses parallel. For example, the first and the second series of pulses start simultaneously. A first frequency of the first series of pulses is lower than a second frequency of the second series of pulses. For example, the first frequency is ½ or ⅓ or ¼ of the second frequency.

In an embodiment, the pixel arrangement comprises a gain capacitor. The gain capacitor can be named dual conversion gain capacitor. The gain capacitor is coupled to a node between the first coupling transistor and the second coupling transistor. The first coupling transistor couples the first circuit node to the gain capacitor. The second coupling transistor couples the second circuit node to the gain capacitor. Advantageously, the input voltage at the input of the amplifier can be changed (e.g. reduced) by setting the first coupling transistor in a conducting state such that charge flows from the first circuit node to the gain capacitor.

In an embodiment, the pixel arrangement comprises a further reset transistor which couples an output of the amplifier to a reference potential terminal.

In an embodiment, the pixel arrangement comprises a first capacitor and a first transistor. The first transistor couples the output of the amplifier to the first capacitor.

In an embodiment, the pixel arrangement comprises a second capacitor and a second transistor. The second transistor couples the first capacitor to the second capacitor.

In an embodiment, the pixel arrangement comprises a third transistor and an output amplifier. The third transistor couples the second capacitor to an input of the output amplifier.

In an embodiment of the pixel arrangement, the pixel arrangement comprises a third capacitor coupled to a node between the third transistor and the input of the output amplifier.

In an embodiment, in a storage phase, the pixel arrangement is configured to store an output voltage of the amplifier in the third capacitor during a first storage phase, in the second capacitor during a second storage phase and in the first capacitor during a third storage phase. The third storage phase is after the second storage phase. The second storage phase is after the first storage phase. The storage phase comprises the first, the second and the third storage phase.

In an embodiment, in the storage phase, the pixel arrangement is configured to set the first coupling transistor and the second coupling transistor in a conducting state during the first and the second storage phase.

In an embodiment, in the storage phase, the pixel arrangement is configured to set the second transfer transistor in a conducting state before the first storage phase, to set the first transfer transistor in a conducting state by a first voltage value between the first storage phase and the second storage phase and to set the first transfer transistor in a conducting state by a second voltage value between the second storage phase and the third storage phase. For example, the second transfer transistor is set by the first voltage value in the conducting state before the first storage phase.

In an embodiment of the pixel arrangement, a conductivity of a controlled section of the first transfer transistor receiving the second voltage value is higher than a conductivity of the controlled section of the first transfer transistor receiving the first voltage value. Thus, a barrier provided by the first transfer transistor is higher between the first storage phase and the second storage phase than between the second storage phase and the third storage phase.

In an embodiment, the pixel arrangement comprises a select transistor that couples an output of the output amplifier to a column line.

In an alternative embodiment, the pixel arrangement comprises a further first capacitor and a further first transistor. The further first transistor couples the output of the amplifier to the further first capacitor.

In an embodiment, the pixel arrangement comprises a further second capacitor and a further second transistor. The further second transistor couples the further first capacitor to the further second capacitor.

In an embodiment, the pixel arrangement comprises a further output amplifier coupled to the further second transistor. The further second capacitor is coupled to a node between the further second transistor and an input of the further output amplifier.

In an embodiment, the pixel arrangement comprises a further select transistor that couples an output of the further output amplifier to a further column line. In an example, the further column line is connected to the column line. In an alternative example, the further column line is not connected to the column line.

In an embodiment of the pixel arrangement, the first and the second transfer transistor, the first and the second coupling transistor, the reset transistor, the further reset transistor, the first, second and third transistor and the select transistor are realized as field-effect transistors, abbreviated FET, such as e.g. metal-oxide-semiconductor field-effect transistors, abbreviated MOSFETs or metal-insulator-semiconductor field-effect transistors, abbreviated MISFETs. Each of them is realized as n-channel FET. In an example, each of them is implemented enhancement mode FET.

In an embodiment of the pixel arrangement, the first and the second transfer transistor have different threshold voltages. The first and the second transfer transistor are n-channel FETs. The threshold voltages of the first and the second transfer transistor are positive. In an example, the threshold voltage of the second transfer transistor is higher than a threshold voltage of the first transfer transistor.

In an example, before the first storage phase a pulse is provided to the second transfer transistor, and after the first storage phase and before the second storage phase a pulse is provided to the first transfer transistor, wherein both pulses have the same voltage value named first voltage value. The output signal of the amplifier in the first storage phase is stored in the third capacitor. The output signal of the amplifier in the second storage phase is stored in the second capacitor. Thus, for example, in a readout phase after the third storage phase, an information about the threshold voltage of the second transfer transistor and the threshold voltage of the first transfer transistor is determined by evaluating the signal stored by the third capacitor and the signal stored by the second capacitor. Said information is for example a difference between the threshold voltage of the second transfer transistor and the threshold voltage of the first transfer transistor or a parameter that depends on the difference.

In an embodiment, an image sensor comprises an array of pixel arrangements.

In an embodiment, the image sensor additionally comprises a timing generator. The timing generator is configured to provide a first transfer signal to a control terminal of the first transfer transistor, a second transfer signal to a control terminal of the second transfer transistor, a first coupling signal to a control terminal of the first coupling transistor, a second coupling signal to a control terminal of the second coupling transistor and a reset signal to a control terminal of the reset transistor. The timing generator is configured to provide signals to the control terminals of each of the transistors of the pixel arrangement.

The pixel arrangement described above is particularly suitable for the image sensor. Features described in connection with the pixel arrangement can therefore be used for the image sensor and vice versa.

In an embodiment, a method for operating a pixel arrangement comprises:
converting electromagnetic radiation into charge by a photodiode, in an exposure phase setting the first transfer transistor and the reset transistor in a conducting state for a first pulse period, and in the exposure phase setting the second transfer transistor in a conducting state and in a non-conducting state during the first pulse period of the first transfer transistor.

The pixel arrangement and the image sensor described above are particularly suitable for the method of operating a pixel arrangement. Features described in connection with the pixel arrangement and the image sensor can therefore be used for the method and vice versa.

In an example, the pixel arrangement is implemented as dual-transfer-gate time-modulation HDR pixel. HDR is the abbreviation for high dynamic range.

In an example, the image sensor is a CMOS image sensor, abbreviated CIS. The image sensor is used e.g. in consumer, home, automotive or industrial applications. The image sensor is realized e.g. for augmented reality/virtual reality, abbreviated AR/VR, robotics, machine vision or security camera applications. In an example, the pixel arrangement could achieve an additional 20 dB of dynamic range for every decade of difference between the pulsing frequency applied to first transfer transistor and the second transfer transistor. The pixel arrangement is implemented as HDR pixel. The pixel arrangement comprises dual transfer gates.

In an example, HDR is difficult to obtain with a voltage domain pixel where a pipeline mode is performed. The described pixel arrangement provides true HDR without impacting the pipeline mode. The pixel arrangement includes at a minimum one additional sample-and-hold capacitor, abbreviated S/H capacitor, for the purpose of obtaining the threshold variation between the first transfer transistor and the second transfer transistor and at minimum one additional transistor prior to the output amplifier. The pixel arrangement also leverages several different timing implementations. The pixel arrangement also provides a CDS HCG and a DDS LCG read resulting in better noise performance across the entire exposure range. LCG being DDS read implements sampling a reset level during the start of the next frame. CDS stands for correlated double sampling and DDS stands for differential double sampling. HCG is the abbreviation for high conversion gain and LCG is the abbreviation for low conversion gain.

In an example, the pixel arrangement realizes a leverage dual transfer gate and time modulation to extend dynamic range. This is achieved with known threshold voltage variation between the first transfer transistor and the second transfer transistor. This calibration level is known on a per pixel basis for the pixel arrangement. The pixel arrangement leverages the barrier modulation approach as a starting point, but pure lateral overflow and time modulation also possible. An improved noise performance is provided by leveraging a minimum of three S/H capacitors. The image sensor is realized e.g. with in-pixel stacking of capacitors resulting in a small pixel pitch. Alternatively, the image sensor is realized e.g. without in-pixel stacking of capacitors resulting in a slightly increased pixel pitch in comparison to the image sensor with in-pixel stacking.

The barrier modulation is described in the international patent applications PCT/US2022/040005 and PCT/US2022/040007, the disclosure content of both is hereby incorporated by reference.

### BRIEF DESCRIPTION OF THE DRAWINGS

The following description of figures of examples or embodiments may further illustrate and explain aspects of the pixel arrangement, the image sensor and the method for operating a pixel arrangement. Arrangements, devices and circuit blocks with the same structure and the same effect, respectively, appear with equivalent reference symbols. In so far as arrangements, devices and circuit blocks correspond to one another in terms of their function in different figures, the description thereof is not repeated for each of the following figures.

FIGS. 1A to 1E show an exemplary embodiment of a pixel arrangement;

FIGS. 2A to 2C show a further exemplary embodiment of a pixel arrangement; and

FIG. 3 shows an exemplary embodiment of an image sensor with a pixel arrangement.

### DETAILED DESCRIPTION OF ILLUSTRATIVE EMBODIMENTS

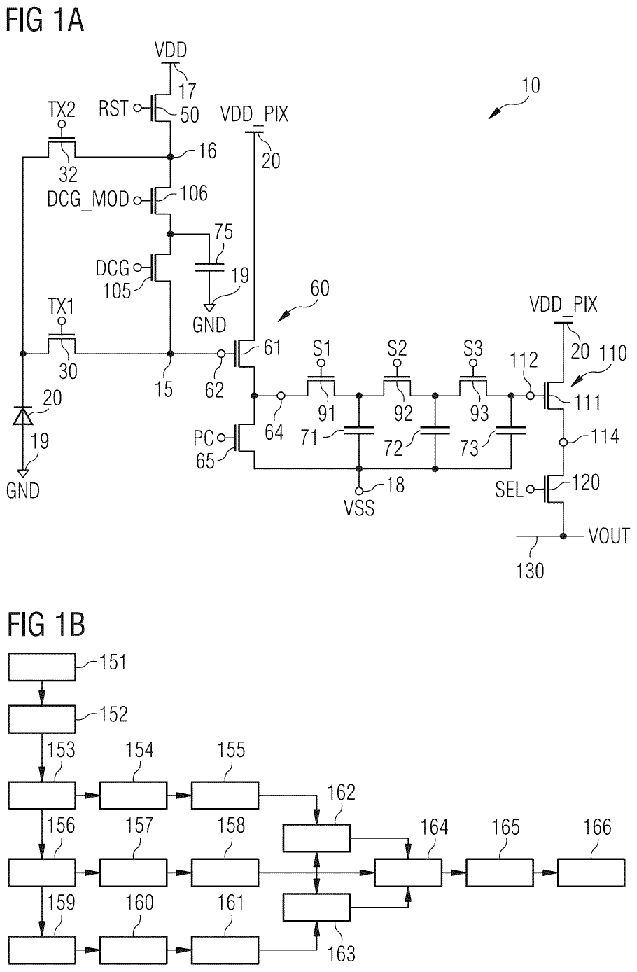

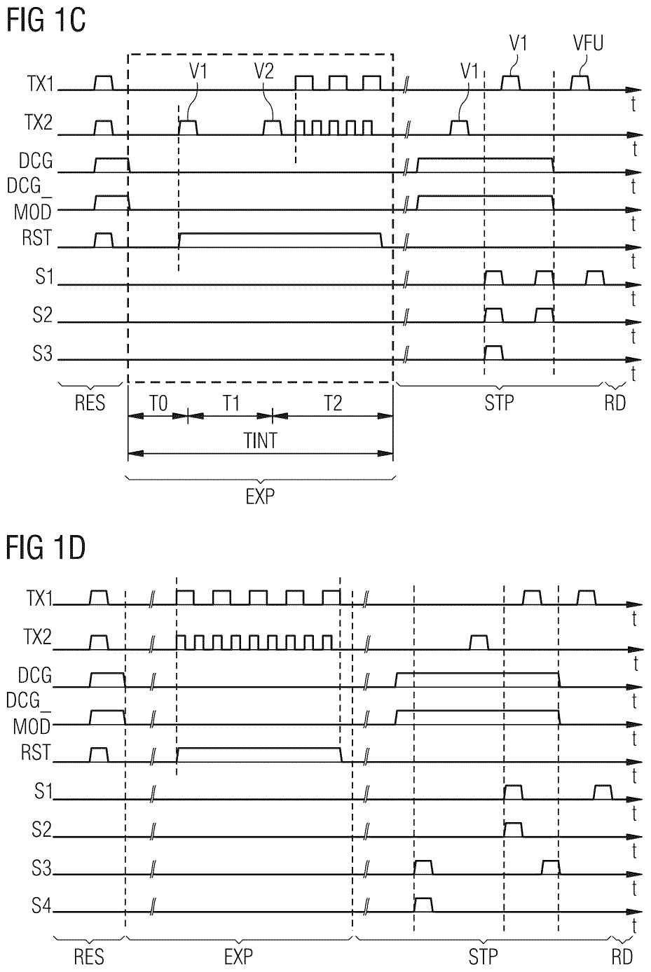

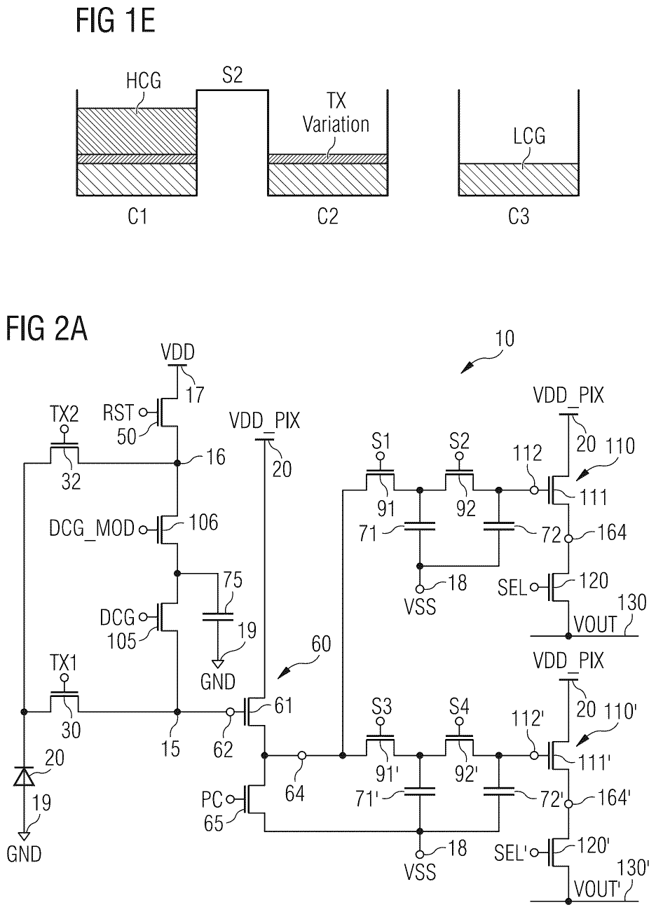

FIG. 1A shows an exemplary embodiment of a pixel arrangement 10. The pixel arrangement 10 comprises a photodiode 20, a first circuit node 15, and a transfer transistor 30 coupled to the photodiode 20 and to the first circuit node 15. A controlled path of the transfer transistor 30 connects a first terminal of the photodiode 20 to the first circuit node 15. The transfer transistor 30 can also be named transfer gate. The first terminal of the photodiode 20 is a cathode. A second terminal of the photodiode 20 is an anode. The pixel arrangement 10 includes an amplifier 60 with an input 62 coupled to the first circuit node 15. The first circuit node 15 has a capacitance which is e.g. a floating diffusion capacitance. The first circuit node 15 is connected to or is equal with a first terminal of the capacitance.

The pixel arrangement 10 includes a first capacitor 71, a second capacitor 72, a first transistor 91 and a second transistor 92. The first and the second transistor 91, 92 can be named first and second switch. The first transistor 91 is coupled to an output 64 of the amplifier 60 and to the first capacitor 71. A controlled path of the first transistor 91 connects the output 64 of the amplifier 60 to a first electrode of the first capacitor 71. The second transistor 92 is coupled to the first transistor 91 and to the second capacitor 72. A controlled path of the second transistor 92 connects a terminal of the first transistor 91 to a first electrode of the second capacitor 72. Thus, the controlled path of the second transistor 92 connects the first electrode of the first capacitor 71 to the first electrode of the second capacitor 72.

The pixel arrangement 10 includes a third capacitor 73 and a third transistor 93. The third transistor 93 can be named third switch. The third transistor 93 is coupled to the second transistor 92 and to the third capacitor 73. A controlled path of the third transistor 93 connects a terminal of the second transistor 92 to a first electrode of the third capacitor 73. Thus, the controlled path of the third transistor 93 connects the first electrode of the second capacitor 72 to the first electrode of the third capacitor 73.

Furthermore, the pixel arrangement 10 includes a column line 130 and an output amplifier 110. The output amplifier 110 has an input 112 and an output 114. The input 112 of the output amplifier 110 is coupled to the third capacitor 73. Thus, the input 112 of the output amplifier 110 is connected to the first electrode of the third capacitor 73 and to a terminal of the third transistor 93. The output 114 of the output amplifier 110 is coupled to the column line 130. The pixel arrangement 10 comprises a select transistor 120 coupled to the column line 130 and to the output 114 of the output amplifier 110.

The first electrode of the first capacitor 71 is coupled to a node between the first transistor 91 and the second transistor 92. A second electrode of the first capacitor 71 is coupled to a reference potential terminal 18 of the pixel arrangement 10. The first electrode of the second capacitor 72 is coupled to a node between the second transistor 92 and the third transistor 93. A second electrode of the second capacitor 72 is coupled to the reference potential terminal 18. The first electrode of the third capacitor 73 is coupled to a node between the second transistor 92 and the third transistor 110. A second electrode of the third capacitor 73 is coupled to the reference potential terminal 18.

The second terminal of the photodiode 20 is connected to a ground terminal 19. A second terminal of the capacitance of the first circuit node 15 is connected to the ground terminal 19. The reference potential terminal 18 is connected to the ground terminal 19 or is not connected to the ground terminal 19.

Moreover, the pixel arrangement 10 comprises a supply terminal 17. The pixel arrangement 10 comprises a first coupling transistor 105, a second coupling transistor 106 and a reset transistor 50 which are serially connected. The second coupling transistor 106 is arranged between the first coupling transistor 105 and the reset transistor 50. The first coupling transistor 105 is coupled to the first circuit node 15 and to a first terminal of the second coupling transistor 106. The reset transistor 50 is coupled to a second terminal of the second coupling transistor 106 and to the supply terminal 17.

The pixel arrangement 10 comprises a second transfer transistor 32 that is coupled to the photodiode 20 and to a second circuit node 16. The second circuit node 16 is arranged between the reset transistor 50 and the second coupling transistor 106. A first terminal of the second transfer transistor 32 is connected to a first terminal of the first transfer transistor 30. A second terminal of the first transfer transistor 30 is connected to the first circuit node 15. A second terminal of the second transfer transistor 32 is connected to the second circuit node 16.

The amplifier 60 includes an amplifier transistor 61 having a control terminal coupled to the input 62 of the amplifier 60. A first terminal of the amplifier transistor 61 is coupled to a further supply terminal 20. A second terminal of the amplifier transistor 61 is coupled to the output 64 of the amplifier 60.

The output amplifier 110 includes an output amplifier transistor 111 having a control terminal coupled to the input 112 of the amplifier 110. A first terminal of the output amplifier transistor 111 is coupled to the further supply terminal 20. A second terminal of the output amplifier transistor 111 is coupled to the output 114 of the amplifier 110.

Additionally, the pixel arrangement 10 comprises a further reset transistor 65 coupled to the output 64 of the amplifier 60 and to the reference potential terminal 18.

In an example, the capacitance of the first circuit node 15 comprises one or more than one of a capacitance of the control terminal of the amplifier transistor 61, a capacitance of a pn junction of a terminal of the transfer transistor 30 and a capacitance of a pn junction of the first terminal of the first coupling transistor 105. Thus, parasitic capacitances of the transistors connected to the first circuit node 15 may result in the capacitance of the first circuit node 15. The value of the capacitance of the first circuit node 15 may be the sum of the values of the parasitic capacitances of the transistors connected to the first circuit node 15. Optionally, the pixel arrangement 10 includes e.g. a capacitor connected to the first circuit node 15; the capacitor may contribute to the capacitance of the first circuit node 15.

A supply voltage VDD is tapped at the supply terminal 17. A further supply voltage VDD_PIX is tapped at the further supply terminal 20. A reference potential VSS is tapped at the reference potential terminal 18. The supply voltage VDD is positive with respect to the reference potential VSS. A ground potential GND is tapped at the ground terminal 19. The ground potential GND is equal to or is different from the reference potential VSS. An output signal VOUT is tapped at the column line 130.

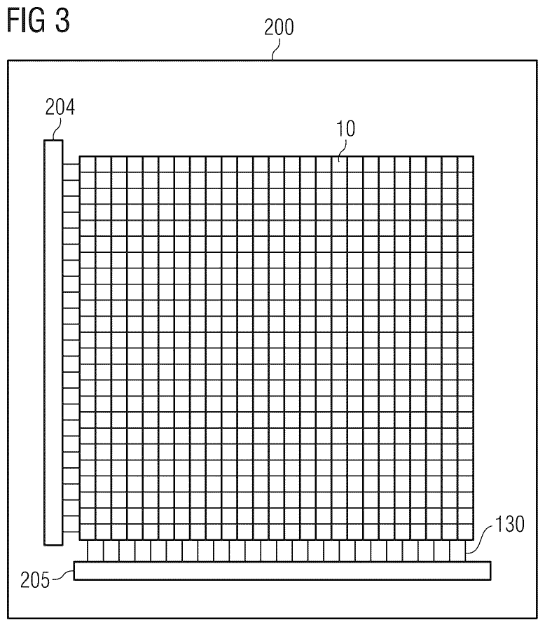

A timing generator 204 (shown in FIG. 3) is coupled to the control terminal of the first transfer transistor 30, of the second transfer transistor 32, of the first coupling transistor 105, of the second coupling transistor 106, of the reset transistor 50, of the further reset transistor 65, of the first transistor 91, of the second transistor 92, of the third transistor 93 and of the select transistor 120. The timing generator 204 provides a first transfer signal TX1 to the first transfer transistor 30, a second transfer signal TX2 to the second transfer transistor 32, a first coupling signal DCG to the first coupling transistor 105, a second coupling signal DCG_MOD to the first coupling transistor 105, a reset signal RST to the reset transistor 50, a further reset signal PC to the further reset transistor 65, a first control signal S1 to the first transistor 91, a second control signal S2 to the second transistor 92, a third control signal S3 to the third transistor 93 and a select signal SEL to the select transistor 120.

The pixel arrangement 10 includes three S/H capacitors 71 to 73 for a voltage domain implementation. In an example, the S/H capacitors 71 to 73 are fabricated with in-pixel stacking or without in-pixel stacking. Moreover, the pixel arrangement 10 includes two additional transistors (e.g. the transistors 32 and 106) prior to output amplifier 110.

Threshold voltage of the second transfer transistor 32>Threshold voltage of the first transfer transistor 30

The different threshold voltages of the first and the second transfer transistors 30, 32 are realized e.g. by different ion implantation processes for the first and for the second transfer transistor 30, 32 (e.g. different ion doses). The delta between the threshold voltages of the first and the second transfer transistors 30, 32 is known with high reliability. An operation without knowing the threshold variation is also possible, but may introduce noise and non-linearity. A dynamic range is extended e.g. by 20 dB or more for every decade of difference between the pulsing frequency of the first and the second transfer transistors 30, 32. Threshold variation between the first and the second transfer transistor 30, 32 is known on a per pixel basis.

The operation is explained using FIGS. 1B to 1E.

FIG. 1B shows an exemplary operation performed by a pixel arrangement 10 which is shown e.g. in FIG. 1A. In FIG. 1B, the operation is shown in blocks. A method for operating the pixel arrangement 10 comprises e.g. the following blocks which can be named procedures or steps:

First block 151: Start exposure. An exposure phase EXP is started.

Second block 152: The transfer barrier is modified based on system input (barrier modulation and time modulation).

Third block 153: A portion of the charge of the photodiode 20 is transferred to the first circuit node 15 via the second transfer transistor 32. More precisely, a portion of the charge of the photodiode 20 is transferred to the first circuit node 15 via the second transfer transistor 32, the second coupling transistor 106 and the first coupling transistor 105.

Fourth block 154: Store charge on the first, second and third capacitor 71 to 73 in a first storage phase ST1.

Fifth block 155: Readout the signal stored by the third capacitor 73 in a readout phase.

Sixth block 156: A portion of the charge of the photodiode 20 is transferred to the first circuit node 15 via the first transfer transistor 30 using same voltage as the partial transfer via the second transfer transistor 32.

Seventh block 157: Store charge on the first and second capacitor 71, 72 in a second storage phase ST2.

Eighth block 158: Readout the signal stored by the second capacitor 72 in the readout phase.

Ninth block 159: The remaining charge of the photodiode 20 is transferred to the first circuit node 15 via the first transfer transistor 30, e.g. using a voltage value VFU.

Tenth block 160: Store charge on the first capacitor 71 in a third storage phase ST3.

Eleventh block 161: Readout the signal stored by the first capacitor 71 in the readout phase.

Twelfth block 162: Subtract the signal that is supplied by the second capacitor 72 from the signal supplied by the third capacitor 73 (transfer transistor variation).

Thirteenth block 163: Subtract the signal that is supplied by the first capacitor 71 from the signal supplied by the second capacitor 72 (high conversion gain).

Fourteenth block 164: A time modulation calibration is performed.

Fifteenth block 165: Per pixel knee point calibration is performed (this block 165 only applies to examples with barrier modulation timing and not for an example with lateral overflow integration capacitor).

Sixteenth block 166: A linearization is performed.

FIG. 1C shows an exemplary timing diagram performed by a pixel arrangement 10 which is shown e.g. in FIGS. 1A and 1B. The following signals are shown as a function of a time t: The first transfer signal TX1, the second transfer signal TX2, the first coupling signal DCG, the second coupling signal DCG_MOD, the reset signal RST and the first control signal S1, the second control signal S2 and the third control signal S3.

The operation includes e.g. a reset phase RES, the exposure phase EXP and the storage phase STP. The storage phase STP follows the exposure phase EXP. The exposure phase EXP follows the reset phase RES.

The operation includes e.g. a readout phase RD that follows the storage phase STP. The storage phase STP comprises the first, second and third storage phase ST1, ST2, ST3. The storage phase STP comprises the blocks 153, 154, 156, 157, 159, 160. The readout phase comprises the blocks 155, 158, 161.

In an alternative way of describing the timing, the readout phase includes the first, second and third storage phase ST1, ST2, ST3. Thus, the readout phase includes the blocks 153 to 161.

The pixel arrangement 10 leverages time modulation to extend dynamic range. The calibration level is known by ensuring the following: Three S/H capacitors 71 to 73 so threshold variation between the first transfer transistor 30 and the second transfer transistor 32 is known on a per-pixel basis. The threshold voltage of the second transfer transistor 32>the threshold voltage of the first transfer transistor 30. This ensures that the calibration level is always known on a per-pixel basis.

The second coupling transistor 106 between the first coupling transistor 105 and the reset transistor 50 allows for: Applying time modulation to extend dynamic range path to supply for extra charge and/or reading LCG value through the second transfer transistor 32 and calibration offset between the first and the second transfer transistor 30, 32.

An example of the timing (Dual Barrier Modulation) includes, wherein integration is performed in the exposure phase EXP:
1. Reset the first circuit node 15, the gain capacitor 75 and the photodiode 20 in the reset phase RES.
2. Start a pre-integration time T0, pulse the second transfer transistor 32 with a first voltage value V1 to dump charge to the supply terminal 17.
3. Start a first integration time T1, pulse the second transfer transistor 32 with a second voltage value V2 to dump charge to the supply terminal 17. In an example, V2<V1.
4. Start a second integration time T2, the first and the second transfer transistors 30, 32 both are pulsing. A dynamic range extension is a function of the modulation ratio between the first and the second transfer signals TX1, TX2 for the second integration time T2 and T1/T0 ratio for the first integration time T1. In an example, T2/T1 is about 1. In an example, T1/T0 is about ⅕.
5. End the exposure phase EXP, end TINT (TINT=T0+T1+T2)

In the storage phase STP:
1. Transfer a LCG signal via the second transfer transistor 32 using the first voltage value V1 to the first circuit node 15 and to the gain capacitor 75 (partial transfer).
2. Sample the LCG signal and overflow charge on the first, second and third capacitor 71 to 73.
3. Transfer a transfer transistor variation via the first transfer transistor 30 using the first voltage value V1 (threshold voltage of the second transfer transistor 32>threshold voltage of the first transfer transistor 30) to the first circuit node 15 and to the gain capacitor 75 (partial transfer).
4. Sample transfer transistor variation on the first and the second capacitor 71, 72.
5. Transfer an HCG signal (remainder of charge of the photodiode 20) to the first circuit node 15 (full transfer).
6. Sample the HCG signal on the first capacitor 71.

FIG. 1D shows an alternative exemplary timing diagram performed by a pixel arrangement 10 as shown e.g. in FIGS. 1A to 1C. An example of the timing using a lateral overflow integration capacitor method, abbreviated LOFIC method (integration):

In the exposure phase EXP:
1. Reset the first circuit node 15, the gain capacitor 75 and the photodiode 20 in the reset phase RES.
2. Start integration time, the first and the second transfer transistors 30, 32 both are pulsing. The first and the second transfer signal TX1, TX2 have pulses with the same magnitude, namely the first voltage value V1. The pulses of the second transfer signal TX2 have a higher frequency than the pulses of the first transfer signal TX1. The reset transistor 50 is held in a conducting state to dump charge to the supply terminal 17.
3. End the exposure phase EXP, end TINT.

In the storage phase STO:
1. Transfer a LCG signal via the second transfer transistor 32 using the first voltage value V1 to the first circuit node 15 and to the gain capacitor 75 (partial transfer).
2. Sample the LCG signal and overflow charge on the first, second and third capacitor 71 to 73.
3. Transfer a transfer transistor variation via the first transfer transistor 30 using the first voltage value V1 (threshold voltage of the second transfer transistor 32>threshold voltage of the first transfer transistor 30) to the first circuit node 15 and to the gain capacitor 75 (partial transfer).
4. Sample transfer transistor variation on the first and the second capacitor 71, 72.
5. Transfer an HCG signal (remainder of charge of the photodiode 20) to the first circuit node 15 (full transfer).
6. Sample the HCG signal on the first capacitor 71.

The example timing leverages the Dual Barrier approach, but instead of achieving HDR by having a T0/T1 and T1/T2 exposure ratio, the T0/T1 ratio is leveraged and then T1/T2 ratio is kept about 1 and time modulation is utilized to extend dynamic range for the second integration time T2.

An additional knob for the HDR signal is added. The exposure time T1 and T2 is e.g. the same reducing limitation of needing a T2 ratio that is a fraction of T1 to achieve additional dynamic range (could be beneficial for short total exposure times). The pixel arrangement 10 leverages e.g. LOFIC, and/or a single barrier approach.

FIG. 1E shows an exemplary potential diagram of the S/H capacitors 71 to 73 of a pixel arrangement 10 as shown e.g. in FIGS. 1A to 1D. The diagram marked with C1 refers to the first capacitor 71, the diagram marked with C2 is related to the second capacitor 72, and the diagram marked with C3 refers to the third capacitor 73.

Example of raw Signals accounting for threshold variation between the first transfer gate 30 and the second transfer gate 32:

$$TX\_calibration = C 2 - C 3$$

$$LCG = C 3$$

DDS operation would use additional reset and sample approach. In an example, the reset level is sampled during the integration of the next frame to achieve DDS with the LCG read.

$$HCG = C 1 - C 2$$

C1 is a signal stored in the first capacitor 71 and provided by the first capacitor 71; C2 is a signal stored in the second capacitor 72; and C3 is a signal stored in the third capacitor 73. LCG is a low-conversion-gain signal and HCG is a high-conversion-gain signal.

### Corrected Signals:

$$Gain\_correction = \frac{HCG}{HCG - TX\_calibration}$$

$$HCG\_corr = \frac{HCG}{Gain\_correction}$$

$$LCG\_corr = LCG \cdot Gain\_correction$$

### Gained Signal (Barrier Modulation Example):

$$HCG\_gain = HCG\_corr$$

$$LCG\_mid = LCG\_corr \frac{T0\_exposure}{T1\_exposure}$$

(the gain LCG_mid is applied to charge accumulated during the first integration time T1)

$$LCG\_high = LCG\_mid \cdot \frac{T1\_exposure}{T2\_exposure} \cdot \frac{TX2\_mod}{TX1\_mod}$$

(the gain LCG_high is applied to charge accumulated during the second integration time T2)

HCG_gain is a high conversion gain signal resulting from the correction steps; LCG_mid and LCG_high are two low conversion gain signals resulting from the correction steps.

### Gained Signal (LOFIC Example):

$$HCG\_gain = HCG\_corr$$

$$LCG\_gain = LCG\_corr \frac{T0\_exposure}{T1\_exposure}$$

LCG_gain is a low conversion gain signal resulting from the correction steps.

The pixel arrangement 10 leverages dual transfer gate and time modulation to extend dynamic range. The pixel arrangement 10 may fail without known threshold voltage variation between TX1 and TX2, this calibration level is known on a per pixel basis for the pixel. The calibration level is known by ensuring the following: Three S/H capacitors so threshold variation between first and second transfer transistors 30, 32 is known on a per-pixel basis. The second transfer transistor 32 has a greater threshold voltage than the first transfer transistor 30. This ensures that the needed calibration level is always known on a per-pixel basis.

The second coupling transistor 106 between the first coupling transistor 105 and the reset transistor 50 allows for:
Applying time modulation to extend dynamic range, resulting in a path to supply for extra charge,
Reading LCG through the second transfer transistor 32, resulting in a LCG value and calibration offset between the first and the second transfer transistors 30, 32.

The pixel arrangement 10 is configured to:

Transfer charge from the photodiode 20 via the first transfer transistor 30 to the first circuit node 15 and to the gain capacitor (thus threshold variation calibration value between the first and the second transfer transistors 30, 32 is achieved).

Dump charge from the photodiode 20 via the second transfer transistor 32 to the supply terminal 17 for dynamic range extension.

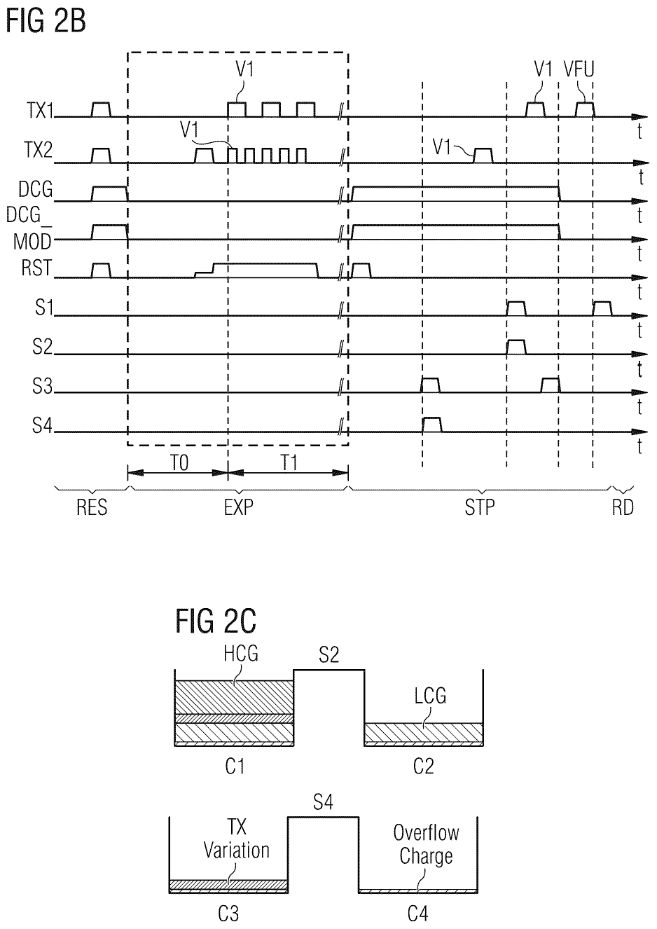

FIG. 2A shows a further exemplary embodiment of a pixel arrangement which is a further development of the embodiment shown in FIGS. 1A to 1E. The pixel arrangement 10 comprises a further first capacitor 71′ and a further first transistor 91′. The further first transistor 91′ couples the output 64 of the amplifier 60 to the further first capacitor 71′. The pixel arrangement 10 comprises a further second capacitor 72′ and a further second transistor 92′. The further second transistor 92′ couples the further first capacitor 71′ to the further second capacitor 72′. The pixel arrangement 10 comprises a further output amplifier 110′ coupled to the further second transistor 92′. The further second capacitor 72′ is coupled to a node between the further second transistor 92′ and an input 112′ of the further output amplifier 110′. The pixel arrangement 10 comprises a further select transistor 120′ that couples an output 114′ of the further output amplifier 110′ to a further column line 130′. In an example, the further column line 130′ is connected to the column line 130.

FIG. 2B shows an alternative exemplary timing diagram of a pixel arrangement 10 as shown e.g. in FIG. 2A.

In the exposure phase EXP:

1. Reset the first circuit node 15, the gain capacitor 75 and the photodiode 20 in the reset phase RES.

2. Start a pre-integration time T0, the second transfer transistor receives a second transfer signal TX2 with the first voltage value V1 to dump charge to the supply terminal 17. In an example, the reset transistor 50 is on to some degree such that charge is dumped via the second transfer transistor 31 to the supply terminal 17. In a not-shown option, the pulse of the reset signal RST starts already during the pulse of the second transfer signal TX2.

3. Start a first integration time T1, the first and the second transfer transistors 30, 32 both are pulsing. A dynamic range extension depends on a pulsing ratio of the first and the second transfer signal TX1, TX2. T1<T0. TINT=T0+T1. In an example, T1/T0 is about ⅕.

4. End the exposure phase EXP, end TINT.

In the storage phase STO:
1. Sample a signal (e.g. a voltage) at the first circuit node and a signal (e.g. a voltage) at the gain capacitor 75 on the further first capacitor 71′ and the further second capacitor 72′.
2. Transfer a LCG signal via the second transfer transistor 32 to the first circuit node 15 and to the gain capacitor 75 using the first voltage value V1 that has been used for barrier modulation during TINT; provide the LCG signal on the on the first and the second capacitor 71, 72.
3. Transfer a transfer transistor variation via the first transfer transistor 30 using the first voltage value V1 (threshold voltage of the second transfer transistor 32>threshold voltage of the first transfer transistor 30) to the first circuit node 15. Sample the transfer transistor variation and to further first capacitor 70′.
4. Transfer an HCG signal (remainder of charge of the photodiode 20) to the first circuit node 15 using a pulse applied to the first transfer transistor 30 with a voltage value VFU. VFU>V1. Sample the HCG signal on the first capacitor 71.

FIG. 2C shows an exemplary potential diagram of the S/H capacitors 71, 72, 71′, 72′ in a pixel arrangement 10 as shown e.g. in FIGS. 2A and 2B. The diagram marked with C1 refers to the first capacitor 71, the diagram marked with C2 is related to the second capacitor 72, the diagram marked with C3 refers to the further first capacitor 71′ and the diagram marked with C4 is related to the further second capacitor 72′.

FIG. 3 shows an exemplary embodiment of an image sensor 100 with a pixel arrangement 10 which is a further development of the above shown embodiments. The image sensor 200 comprises an array of pixel arrangements 10. Moreover, the image sensor 200 further comprises the timing generator 204 that provides the different signals TX1, TX2, DCG, DCG_MOD, RST, PC, S1, S2, S3 and SEL. The timing generator 204 provides these signals for each of the rows. The image sensor 200 includes an evaluation circuit 205 for digitizing the output signals VOUT at the column lines 130.

The pixel arrangement 10 can be used in different embodiments such as e.g. in a VGS pixel, in a rolling shutter pixel, in a global shutter pixel, in any system where dual transfer gates are used with threshold voltage of one transfer gate engineered to have a higher threshold voltage for the purpose of calibrating threshold variations, and in any system where dual transfer gates are used providing a path to the supply terminal 17 and the first circuit node 15 (realized as floating diffusion node). The pixel arrangement 10 additionally includes the second transfer transistor 32 and the second coupling transistor 106 with the purpose of 1.) reading signal charge and 2.) dumping charge to the supply terminal 17. The image sensor 200 applies the sample partial pulse to the first and the second transfer transistor 30, 32 to obtain threshold variation.

In an alternative, not shown embodiment, the pixel arrangement 10 comprises a third transfer transistor and an additional coupling transistor. The additional coupling transistor is arranged between the second circuit node 16 and the reset transistor 50. The third transfer transistor couples the photodiode 20 to a third circuit node that is between the additional coupling transistor and the reset transistor 50. An additional gain capacitor is coupled to the second circuit node 16 or to the third circuit node. Thus, the dynamic range can be further extended.

The present disclosure is not limited to the description of the embodiments. Rather, the present disclosure comprises each new feature as well as each combination of features, particularly each combination of features of the claims, even if the feature or the combination of features itself is not explicitly given in the claims or embodiments.

1. A pixel arrangement, comprising:
a photodiode,
a first and a second circuit node,
a first transfer transistor coupled to the photodiode and to the first circuit node,
a second transfer transistor coupled to the photodiode and to the second circuit node,
an amplifier with an input coupled to the first circuit node,
a supply terminal,
a first and a second coupling transistor, and
a reset transistor,
wherein the first coupling transistor, the second coupling transistor and the reset transistor are serially coupled and are arranged between the supply terminal and the first circuit node, and
wherein the second circuit node is arranged between the second coupling transistor and the reset transistor.

2. The pixel arrangement of claim 1,
wherein in an exposure phase the pixel arrangement is configured
to set the first transfer transistor and the reset transistor in a conducting state for a first pulse period and
to set the second transfer transistor in a conducting state and in a non-conducting state during the first pulse period of the first transfer transistor.

3. The pixel arrangement of claim 2,
wherein in the exposure phase the pixel arrangement is configured
to set the first transfer transistor in a conducting state for a second pulse period and in a non-conducting state during an in-between period between the first pulse period and the second pulse period,
to set the reset transistor in a conducting state during the second pulse period and during the in-between period between the first pulse period and the second pulse period,
to set the second transfer transistor in a conducting state and in a non-conducting state in the in-between period between the first pulse period and the second pulse period and
to set the second transfer transistor in a conducting state and in a non-conducting state during the second pulse period of the first transfer transistor.

4. The pixel arrangement of claim 1,
wherein the pixel arrangement is configured
to set the first transfer transistor in a conducting state during pulses of a first series of pulses and to set the first transfer transistor in a non-conducting state during in-between periods between pulses of the first series of pulses,
to set the reset transistor in a conducting state during the pulses of the first series of pulses and during the in-between periods between the pulses of the first series of pulses,
to set the second transfer transistor in a conducting state during pulses of a second series of pulses and in a non-conducting state during in-between periods between the pulses of the second series of pulses, and
to perform the first and the second series of pulses parallel, and
wherein a first frequency of the first series of pulses is lower than a second frequency of the second series of pulses.

5. The pixel arrangement of claim 1,
wherein the pixel arrangement comprises a gain capacitor which is coupled to a node between the first coupling transistor and the second coupling transistor.

6. The pixel arrangement of claim 1,
wherein the first and the second transfer transistor are realized as field-effect transistors,
wherein the first transfer transistor has a first threshold voltage and the second transfer transistor has a second threshold voltage, and
wherein the first threshold voltage is different from the second threshold voltage.

7. The pixel arrangement of claim 1,
wherein the pixel arrangement comprises a further reset transistor which couples an output of the amplifier to a reference potential terminal.

8. The pixel arrangement of claim 1,
wherein the pixel arrangement comprises a first capacitor and a first transistor, and
wherein the first transistor couples an output of the amplifier to the first capacitor.

9. The pixel arrangement of claim 8,
wherein the pixel arrangement comprises a second capacitor and a second transistor, and
wherein the second transistor couples the first capacitor to the second capacitor.

10. The pixel arrangement of claim 9,
wherein the pixel arrangement comprises a third transistor and an output amplifier, and
wherein the third transistor couples the second capacitor to an input of the output amplifier.

11. The pixel arrangement of claim 10,
wherein the pixel arrangement comprises a third capacitor coupled to a node between the third transistor and the input of the output amplifier.

12. The pixel arrangement of claim 11,
wherein the pixel arrangement is configured to store an output voltage of the amplifier in the third capacitor during a first storage phase, in the second capacitor during a second storage phase and in the first capacitor during a third storage phase.

13. The pixel arrangement of claim 12,
wherein the pixel arrangement is configured to set the first coupling transistor and the second coupling transistor in a conducting state during the first and the second storage phase.

14. The pixel arrangement of claim 12,
wherein the pixel arrangement is configured
to set the second transfer transistor in a conducting state by a first voltage value before the first storage phase,
to set the first transfer transistor in a conducting state by the first voltage value between the first storage phase and the second storage phase and
to set the first transfer transistor in a conducting state by a second voltage value between the second storage phase and the third storage phase and
wherein a conductivity of a controlled section of the first transfer transistor receiving the second voltage value is higher than the conductivity of the controlled section of the first transfer transistor receiving the first voltage value.

15. (canceled)

16. The pixel arrangement of claim 9,
wherein the pixel arrangement comprises a further first capacitor and a further first transistor, and
wherein the further first transistor couples the output of the amplifier to the further first capacitor.

17. The pixel arrangement of claim 16,
wherein the pixel arrangement comprises a further second capacitor and a further second transistor, and
wherein the further second transistor couples the further first capacitor to the further second capacitor,
wherein the pixel arrangement comprises a further output amplifier with an input coupled to the further second transistor, and
wherein the further second capacitor is coupled to a node between the further second transistor and the input of the further output amplifier.

18. (canceled)

19. An image sensor, comprising
an array of pixel arrangements according to claim 1, and
a timing generator configured to provide a first transfer signal to a control terminal of the first transfer transistor, a second transfer signal to a control terminal of the second transfer transistor, a first coupling signal to a control terminal of the first coupling transistor, a second coupling signal to a control terminal of the second coupling transistor and a reset signal to a control terminal of the reset transistor.

20. A method for operating a pixel arrangement, comprising:
converting electromagnetic radiation into charge by a photodiode,
in an exposure phase setting the first transfer transistor and the reset transistor in a conducting state for a first pulse period and
in the exposure phase setting the second transfer transistor in a conducting state and in a non-conducting state during the first pulse period of the first transfer transistor.

21. A pixel arrangement, comprising:
a photodiode,
a first and a second circuit node,
a first transfer transistor coupled to the photodiode and to the first circuit node,
a second transfer transistor coupled to the photodiode and to the second circuit node,
an amplifier with an input coupled to the first circuit node,
a supply terminal,
a first and a second coupling transistor,
a reset transistor, and
three sample-and-hold capacitors,
wherein the first coupling transistor, the second coupling transistor and the reset transistor are serially coupled and are arranged between the supply terminal and the first circuit node, and
wherein the second circuit node is arranged between the second coupling transistor and the reset transistor.

22. The pixel arrangement of claim 21,
wherein the three sample-and-hold capacitors comprise
a first capacitor,
a second capacitor, and
a third capacitor or a further first capacitor.
